(19) United States
(12) Patent Application Publication
(10) Pub. No.: US 2006/0076233 A1
(43) Pub. Date: Apr. 13, 2006

(54) Magnetic recording medium and method for production thereof

(75) Inventors: Yoshinori Honda, Kanagawa-ken (JP); Ikuko Takekuma, Kanagawa (JP); Ichiro Tamai, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(73) Assignee: Hitachi Global Storage Technologies Netherlands B.V., Amsterdam (NL)

(21) Appl. No.: 11/246,344

(22) Filed: Oct. 6, 2005

(30) Foreign Application Priority Data
Oct. 7, 2004 (JP) 2004-294550

(51) Int. Cl. C23C 14/00

(52) U.S. Cl. 204/192.15; 204/192.2

(57) ABSTRACT

A reactive sputtering method is provided for producing a magnetic layer in a stable manner with good reproducibility. One aspect of the invention is to form a magnetic layer for a magnetic recording medium without adversely affecting magnetic properties. Carbon oxide gas is added at the time of reactive sputtering. In one embodiment, a method for producing a magnetic recording medium includes forming at least a soft magnetic layer and a magnetic layer above a substrate, wherein forming said magnetic layer includes sputtering with argon gas and carbon oxide gas.

### CROSS-REFERENCES TO RELATED APPLICATIONS

This application claims priority from Japanese Patent Application No. JP2004-294550, filed Oct. 7, 2004, the entire disclosure of which is incorporated herein by reference.

### BACKGROUND OF THE INVENTION

The present invention relates to magnetic recording media and a method for production thereof, and particularly to a magnetic recording medium adaptable to HDD (hard disk drive). The present invention relates also to a magnetic storage device using the magnetic recording medium.

In compliance with the demand for a higher recording density than before, extensive improvements are being made in the magnetic recording medium, particularly the magnetic disk for HDD, by increasing the coercive force (Hc) to a great extent. However, meeting this demand is difficult so long as the conventional ferromagnetic CoCrPt alloy is used for the magnetic layer of the magnetic disk, because its coercive force has already reached the limit. On the other hand, the conventional longitudinal recording system has a problem with thermal stability, and there is a demand for solving this problem. Thermal stability is a phenomenon in which signals recorded in magnetic recording media attenuate with the lapse of time, eventually to the noise level of recording media, at which recorded signals cannot be read any longer. This results from the extremely fine magnetic particles which have been adopted to raise the S/N ratio, thereby meeting the demand for high recording density. One way of solving this problem is to adopt the perpendicular magnetic recording system in place of the longitudinal recording system. The perpendicular magnetic recording system is expected to achieve a sufficiently high S/N ratio while keeping good thermal stability in the region of high recording density. The medium for perpendicular magnetic recording is usually composed of a perpendicular magnetic recording layer which is a perpendicular magnetizing layer to record information signals, a soft magnetic layer which is designed to improve the signal recording-reproducing efficiency, and a plurality of non-magnetic layers which achieve crystallinity improvement and crystal size control for the perpendicular magnetic recording layer.

Patent Document 1 (Japanese Patent Laid-open No. 2003-151117) reports that the increase of coercive force in the magnetic layer of the magnetic disk has reached its limits so long as a CoCrPt alloy is used. Patent Document 2 (Japanese Patent Laid-open No. 5-114103) discloses a perpendicular recording medium of a CoPt alloy. Patent Document 3 (Japanese Patent Laid-open No. 2002-343667) discloses a process for introducing a gas of M₂(CO)₈ (M=magnetic metal or alloy) into a chamber, while irradiating the gas with a scanning Ga cation beam, thereby forming particles of M.

### BRIEF SUMMARY OF THE INVENTION

The present inventors carried out investigations as below to form consistently a magnetic layer excelling in magnetic properties suitable for the perpendicular magnetic recording system. Among perpendicular magnetic layers is one which is called a granular magnetic layer. It is composed of CoCrPt magnetic alloy and an insulating material, such as SiO₂. Its disadvantage is that SiO₂ has a low transition temperature below 200° C. On the other hand, it has the advantage of being formed at approximately room temperature, unlike the conventional longitudinal recording medium which heeds substrate heating. The perpendicular magnetic layer is usually formed by sputtering. Sputtering may be either RF (high-frequency) sputtering or pulse DC sputtering. Sputtering for the granular magnetic layer is naturally reactive sputtering because the target contains SiO₂. In reactive sputtering, oxygen evolved at the time of sputtering greatly affects the magnetic properties of the perpendicular magnetic layer. It is common practice to add oxygen to Ar as a sputtering gas to supplement oxygen evolved from the target. Reactive sputtering, regardless of sputtering system, involving oxygen promotes reaction between metal and oxygen, thereby deteriorating the magnetic properties of the perpendicular magnetic layer. This is true for sputtering of metal on the perpendicular magnetic layer. Thus, there is a demand for a stable process of forming a perpendicular magnetic layer. The following reactions are conceivable in the conventional sputtering with a composite target (CoCrPt alloy plus SiO₂ particles) and a mixed gas (Ar plus O₂).
SiO₂+Ar→SiO+O
SiO+O₂→SiO₂+O
M+O→MO
The result of these reactions is the occurrence of excessive oxygen in the chamber. Excessive oxygen is likely to produce Co or Cr oxide. Co oxide seriously affects the magnetic properties and Cr oxide vaporizes in a vacuum because of its low melting point. The Cr oxide gas is discharged from the system, and this greatly changes the composition of the magnetic layer formed on the substrate. These findings led to the present invention, which is intended to produce a magnetic layer without its magnetic properties being deteriorated by oxygen evolved in its forming process.

The invention disclosed in the present application is briefly represented as below in terms of its typical embodiment. In a process for producing a magnetic recording medium having at least a soft magnetic layer and a magnetic layer formed on a substrate, a sputtering step employs argon gas in combination with carbon oxide to form the magnetic layer. The process according to the present invention is capable of forming the magnetic layer without generating excess oxygen detrimental to its characteristic properties, thereby producing magnetic recording media with improved magnetic properties.

### BRIEF DESCRIPTION OF THE DRAWINGS

FIG. 1 is a schematic diagram showing the layer structure of the perpendicular magnetic recording medium according to the present invention.

FIG. 2 is a schematic diagram showing the continuous multi-layer layer-forming apparatus used in the examples of the present inventions.

FIG. 3 is a graph showing how incorporation with oxygen affects magnetic properties in continuous layer forming operation.

FIG. 4 is a graph showing the relationship between the concentration of CO or CO₂ added and the magnetic property in the examples of the present invention.

FIG. 5 is a graph showing how the concentration of CO₂ or O₂ added affects the flying performance in the examples of the present invention.

FIG. 6 is a graph showing how incorporation with CO or CO₂ affects the stability and reproducibility of continuous operation in the examples of the present invention.

### DETAILED DESCRIPTION OF THE INVENTION

In what follows, some embodiments of the magnetic recording medium and its manufacturing process according to the present invention will be described in detail with reference to the accompanying drawings. Incidentally, the cited drawings may not be to exact scale but may be partly enlarged for easy understanding. Also, the listed materials for layers constituting the magnetic recording medium are not limitative; but any material can be selected according to the desired performance and layer structure.

The magnetic recording medium according to the present invention is that of metal thin film type, which has a magnetic thin film composed mainly of Co—Cr—Pt alloy as a ferromagnetic material on the substrate.

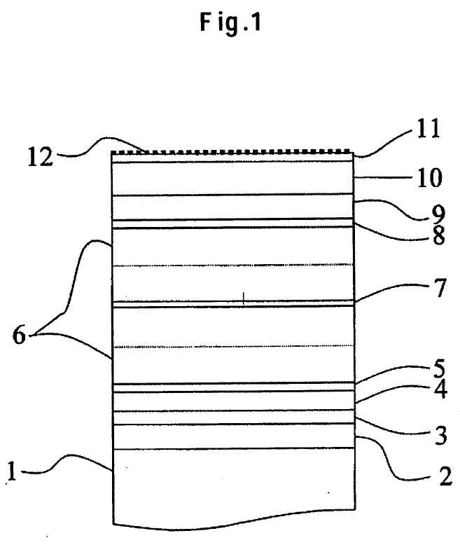

The magnetic recording medium according to specific embodiments of the present invention is characterized by the typical layer structure shown in FIG. 1. There are shown the following layers sequentially formed one over another on a substrate 1: an adhesion layer 2, a crystal orientation control layer 3, an antiferromagnetic layer 4, a magnetic domain fixing enhancement layer 5, a soft magnetic layer 6, a non-magnetic layer 7, a precoat layer 8, an orientation control layer 9, a magnetic layer 10, a protective layer 11, and a lubricating layer 12. The crystal orientation control layer 3 functions to fix the magnetic domains of the soft magnetic layer 6. The non-magnetic layer 7 is that of APC-SUL (antiparallel coupling-soft underlayer) structure which induces magnetic coupling with the soft magnetic layer 6. The precoat layer 8 is an underlying layer to control the crystal orientation of the magnetic layer 10. The orientation control layer 9 controls crystal orientation and grain particles. The magnetic layer 10 takes charge of recording. The protective layer 11 is intended to protect the magnetic recording medium. The lubricating layer 12 relieves shocks resulting from contact with the magnetic head.

The magnetic layer 10 is obtained by reactive sputtering that employs a target composed of Co, Cr, and Pt as major components and silicon oxides as a minor component and a sputtering gas composed of Ar mixed with carbon oxide which is either carbon monoxide (CO) or carbon dioxide (CO₂). In other words, it is a ferromagnetic substance which includes mainly Co, Cr, and Pt and also contains silicon oxides (SiO and SiO₂) and a small amount of carbon (C). In the magnetic layer of granular structure, the CoCrPt-based magnetic crystal cores are coated with SiO₂ segregating in the grain boundary. This SiO₂ breaks the magnetic coupling between the magnetic cores, thereby producing the perpendicular magnetic anisotropy. The mechanism mentioned above suggests that there should exist a certain substance in the grain boundary which does not attack, dissolve, or infiltrate into the CoCrPt-based magnetic crystal cores. Thus, the present inventors conceived that not only will carbon (C) meet this requirement but it also replenishes oxygen releasing itself from SiO₂ due to dissociation, reduces excess oxygen, and promotes segregation in the grain boundary. According to the present invention, the supply of carbon is accomplished by adding carbon oxide gas (CO or CO₂) to the sputtering gas. Reactions involved in such sputtering may be represented as below.
SiO₂+Ar→SiO+O or Si+2O
SiO+O+CO→SiO₂+CO
SiO+CO₂→SiO₂+CO
Si+CO₂→SiO+CO, SiO₂+C
Si+CO→SiO+C
2O+C→CO₂
2O+2C→2CO

These reactions cause excess oxygen to be captured by carbon and also cause Si and SiO to be oxidized by oxygen originating from CO or CO₂. Moreover, these reactions proceed almost in equilibrium. In this way it is possible to accomplish stable, efficient, reproducible sputtering which prevents the oxidation of metals, such as Co, Cr, and Pt, constituting the magnetic layer but permits the captured carbon to promote segregation. Sputtering in the present invention is not specifically restricted in its method. Any method with RF (high-frequency), DC, AC, or pulse DC is adaptable. Incidentally, carbon (C) is susceptible to segregation on account of its high melting point. Consequently, it promotes dissociation by silicon oxides when the magnetic layer is formed.

The SiO₂-containing Co—Cr—Pt target should have a composition such that SiO₂ accounts for no less than 5 mol % and no more than 15 mol % of the amount of Co—Cr—Pt. The thickness of the magnetic layer 10 should be no less than about 5 nm and no more than about 20 nm. The coercive force of the magnetic layer 10 should be in the range of no less than 4 kOe and less than 8 kOe.

Moreover, the content of SiO₂ in the target should preferably be no less than 5 mol % and no more than 15 mol % so that the magnetic head works to its full capacity. The thickness of the magnetic layer 10 should preferably be no less than about 7 nm and no more than about 17 nm. The coercive force of the magnetic layer 10 should preferably be no less than 5.5 kOe and no more than 7 kOe.

The amount of CO or CO₂ to be added to argon (Ar) when the magnetic layer 10 is formed should be in the range of about 0.5% to 6%, which is sufficient to reduce excess oxygen during sputtering.

The substrate shown in FIG. 1 may be formed from any material. A glass substrate, ceramics substrate, or aluminum substrate plated with Ni—P is desirable for laminate film stress, heat resistance, flatness, and smoothness. The substrate should have an adequate surface roughness which depends on the flying height of the magnetic head. The centerline average roughness should preferably be no more than 0.3 nm and the maximum peak height should preferably be no more than 5 nm. This requirement will be met by double-side simultaneous polishing with diamond abrasive grains. The polished substrate may have, without causing any problem, the so-called texture (left after polishing) in its circumferential direction.

The adhesion layer 2 shown in FIG. 1 should bond the upper layer to the substrate with a sufficient adhesion force to overcome the stress resulting from many layers laminated on the upper layer. It may be formed from nickel (Ni) alloy, cobalt (Co) alloy, or aluminum (Al) alloy. These alloys are exemplified by nickel-tantalum (Ni40Ta), nickel-tantalum-zirconium (Ni30Ta10Zr), nickel-aluminum (Ni30Al), nickel-chromium (Ni30Cr), cobalt-titanium (Co20Ti), cobalt-titanium (Co50Ti), cobalt-tantalum (Co20Ta), and aluminum-tantalum (Al50Ta). The adhesion layer 2 may be formed by ordinary DC sputtering; it may be amorphous or crystalline, depending on its purpose.

The crystal orientation control layer 3 as the magnetic domain fixing layer, the antiferromagnetic layer 4, and the magnetic domain fixing enhancement layer 5, which are shown in FIG. 1, are intended to fix magnetic domains in the soft magnetic layer. The magnetic domain fixing layer may be omitted in some cases. The crystal orientation control layer 3 may be formed from a material having the FCC structure or BCC structure. Such a material is exemplified by nickel-iron (NiFe) (permalloy), cobalt-iron (CoFe), and cobalt-chromium (CoCr). The antiferromagnetic layer 4 may be formed from manganese (Mn) alloy, such as manganese-iridium (MnIr) and manganese-iron (FeMn). The magnetic domain fixing enhancement layer 5, which may be omitted in some cases, enhances the coupling force of the antiferromagnetic layer. It may be formed from cobalt-iron (CoFe), nickel-iron (NiFe), or cobalt-chromium (CoCr).

The soft magnetic layer 5, which is formed on the magnetic domain fixing enhancement layer 5 as shown in FIG. 1, is not specifically restricted so long as it has a saturated magnetic flux density (Bs) high enough to return, without magnetic resistance, the magnetic flux from the short-axis magnetic head to the return magnetic pole of the head. The value of Bs may range from 0.8 to 3.0 T. The soft magnetic layer 6 may have a thickness ranging from 50 to 300 nm. The soft magnetic layer 6 may assume the pinned-APC (anti-parallel coupling) structure with the magnetic domain fixing layer or the APC structure or unbalance APC structure without the magnetic domain fixing layer. The soft magnetic layer 6 may be formed from any material having a high value of Bs, which is exemplified by cobalt-tantalum-zirconium (CoTaZr), cobalt-niobium-zirconium (CoNbZr), cobalt-tantalum-niobium (CoTaNb), cobalt-iron-boron (CoFeB), nickel-iron (NiFe), iron-tantalum-carbon (FeTaC), iron-tantalum-boron (FeTaB), iron-tantalum-copper-carbon (FeTaCuC), and iron-tantalum-copper (FeTaCu). These laminate layers may be made to have the APC structure by inserting a non-magnetic layer of ruthenium (Ru), copper (Cu), carbon (C), or ruthenium-cobalt (RuCo).

As shown in FIG. 1, on the soft magnetic layer 6 is the precoat layer 8, which functions as an underlying layer. On the precoat layer 8 is the crystal orientation control layer 9. These two layers 8 and 9 are intended to control crystal gain size and crystal orientation. They are formed from nickel-iron (NiFe), tantalum (Ta), tungsten (W), ruthenium (Ru), ruthenium-cobalt (RuCo), copper (Cu), titanium (Ti), cobalt-titanium (CoTi), or aluminum-titanium (AlTi). More than one of these materials may be used to form a laminate structure. The layer thickness may vary depending on the intended use. For improvement in crystal orientation and magnetic recording characteristics, the total thickness of the underlying layer should preferably be in the range of 5 to 20 nm, because an excessively large distance between the magnetic head and the soft magnetic layer 6 adversely affects the RW characteristics.

The magnetic layer 10 shown in FIG. 1 may be a granular magnetic layer composed of CoCrPt and an oxide as an additional component, or a magnetic layer of superlattice structure which is a superlattice film of Co/Pt incorporated with an oxide. The thickness of the magnetic layer 10 should preferably be about 10 to 20 nm. The granular structure is one in which an oxide matrix contains magnetic particles embedded therein. To be concrete, the granular structure consists of crystal grains containing CoCrPt that are separated from each other by silicon dioxide as a non-magnetic material. The coercive force (Hc) as the magnetic property of the magnetic layer should be no lower than 5 kOe, depending on the combination with the magnetic head. The desired value in the present invention is 7 kOe.

The protective layer 11 shown in FIG. 1 is a carbon layer or a DLC (diamond-like carbon) layer formed by CVD or IBD process. The carbon layer or DLC layer should desirably be incorporated with nitrogen or hydrogen so that it exhibits good adhesion to the lubricating layer 12 to be formed thereon from a fluorine-based liquid lubricating agent.

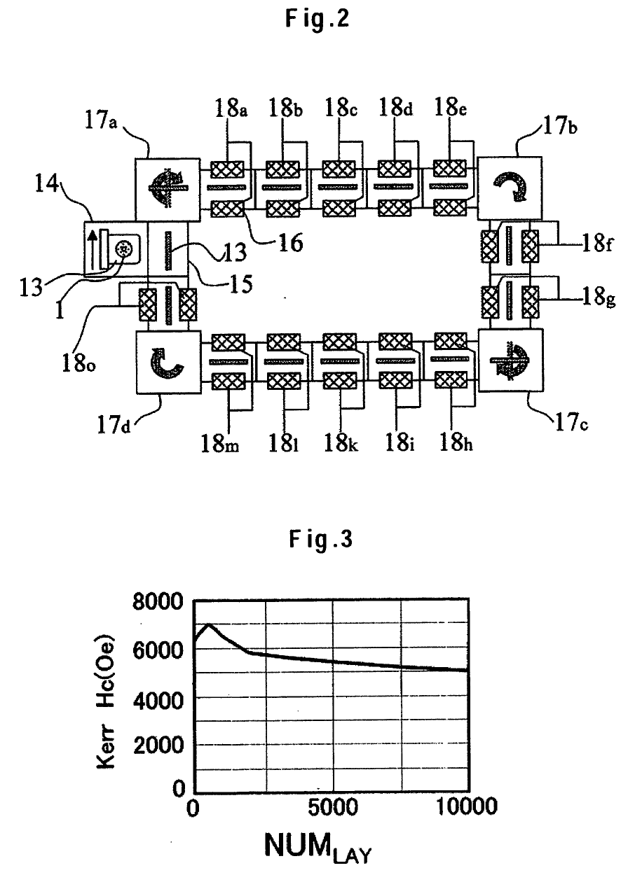

A description is given below of the process for producing the magnetic recording medium shown in FIG. 1. The process is based on sputtering to sequentially form layers on a substrate by using a continuous multi-layer sputtering apparatus shown in FIG. 2. Prior to sputtering, the substrate undergoes surface preparation for the adequate surface roughness, cleaning, and drying.

The multi-layer sputtering apparatus shown in FIG. 2 is comprised of a loading/unloading chamber 15, corner chambers 17a to 17d, sputtering electrodes 18a to 18o, and processing chambers 16. The loading/unloading chamber 15 has a holder 13 to support and transport the substrate 1 and also has a counterturn mechanism to convey the substrate 1. Each of the corner chambers 17a to 17d has a mechanism to convey to the loading/unloading chamber 15 and the holder 13. Each of the sputtering electrodes 18a to 18o is provided with a target for layer, a magnetic circuit, and a sputtering power source. Each of the processing chambers 16 has a gate valve for isolation, a conveying mechanism, and an evacuation pump. The holder 13 supporting the substrate 1 passes through the processing chambers 16, in which the layers are sequentially formed. The sputtering electrode 18 consists of two opposing poles arranged in each chamber. The holder 13 supporting the substrate 1 is brought into the gap between the opposing poles of the electrode 18. While it rests there, the chamber is supplied with a sputtering gas such as Ar from the process gas line attached to the processing chamber 16. With the sputtering gas kept at a prescribed pressure, sputtering is performed to form each layer. Throughout the layer forming process, all the chambers are kept at a high degree of vacuum, with a pressure no higher than 2×10⁻⁵ Pa. The pressure in the processing chamber 16 at the time of layer forming ranges from 0.5 to 6 Pa. Incidentally, this pressure may range from 3 to 5 Pa when the magnetic layer is formed. A bias voltage may occasionally be applied to the substrate in the case where higher performance is required.

In the present invention, DC magnetron sputtering is employed because of its high efficiency. However, it is also possible to use ordinary metal/alloy sputtering, reactive sputtering, RF sputtering, and pulse DC sputtering.

The protective layer 11 of DLC is formed on the uppermost surface by RF-CVD process. The process gas for CVD is ethylene gas incorporated with a prescribed amount of hydrogen and nitrogen. During CVD process, the sputtering electrode 18o is supplied with RF electric power and the substrate 1 is supplied with a bias voltage by the bias mechanism. The pressure of ethylene gas is 2 to 3 Pa and the amount of hydrogen and nitrogen is 5 to 30% and 1 to 3%, respectively. The duration of CVD process, the RF electric power, and the bias voltage are properly adjusted so that the protective layer 11 may have a thickness of 3 to 5 nm.

After the layer forming process is completed, the magnetic recording medium is discharged from the vacuum apparatus. It is finally finished with a fluorine-based lubricant by dip coating. The finished surface is rubbed with a vanish head for removal of anomalous projections and dust. This step is intended for the magnetic head to maintain a prescribed flying height.

The present invention is directed to an improved method for forming the perpendicular magnetic layer of granular type, wherein the improvement is accomplished by incorporation with a substance to control oxygen as a limiting factor of reactions. A possible candidate for such a substance is hydrogen (H₂) which reduces oxygen. However, intentionally added hydrogen might give rise to reaction products, such as OH and H₂O, which are undesirable for the process of forming the magnetic layer. Thus, the present invention employs carbon oxide gas in place of hydrogen, which produces equilibrium reactions for the stable, reproducible layer forming process.

Coercive Force vs. Carbon Oxide Concentration

Several samples of the magnetic recording medium constructed as mentioned above were prepared by sequentially forming the adhesion layer 2 up to the crystal orientation control layer 9 on the substrate, with the magnetic layer 10 formed under varied conditions. The resulting samples were tested for magnetic properties.

Each sample was prepared as below by sputtering on a previously cleaned glass substrate, 65 mm in diameter and 0.635 mm in thickness, with a surface roughness (Ra) of 0.320 nm. First, the substrate was placed in the continuous multi-layer sputtering apparatus shown in FIG. 2. On the substrate was formed the adhesion layer 2 with 30 nm thick by sputtering with a target of Ni40Ta functioning as the DC magnetron cathode excited at 500 W. The chamber was supplied with argon (Ar) at 1.25 Pa. Incidentally, any substrate may substitute for the glass substrate used in this embodiment.

Then, three magnetic domain fixing layers having respective thicknesses of 10, 20, and 5 nm were formed from NiFe20, MnIr20, and CoFe30, respectively. The chamber was supplied with argon (Ar) at 1 Pa for each layer. The DC magnetron cathode was supplied with a power of 500 W, 1 kW, and 300 W for respective layers.

Then, three layers as the soft magnetic layer 6 of APC-SUL structure were formed from Co10Ta5Zr (100 nm thick), Ru (1 nm thick), and Co10Ta5Zr (100 nm thick), respectively. The chamber was supplied with argon (Ar) at 0.6 Pa for each layer. The DC magnetron cathode was supplied with a power level of 2 kW for CoTaZr and 100 W for Ru.

The underlying layer of dual structure, composed of a Ta layer with 3 nm thick and a Ru layer with 15 nm thick, was formed by supplying the chamber with argon (Ar) at 1 Pa and 4 Pa, respectively.

The magnetic layer 10 was formed by using the DC magnetron cathode, with the process gas kept at 3.8 Pa and the DC power level kept at 500 W. Duration of layer forming was varied so that the resulting layer may have a constant thickness of 16 nm. The target was composed of CoCrPt (18-17) plus 10 mol % of SiO₂. The process gas was Ar+CO, Ar+CO₂, or Ar+O₂ for comparison. The ratio of CO, CO₂, or O₂ to argon (Ar) was varied to see their effect on the magnetic properties and to find their optimum amount.

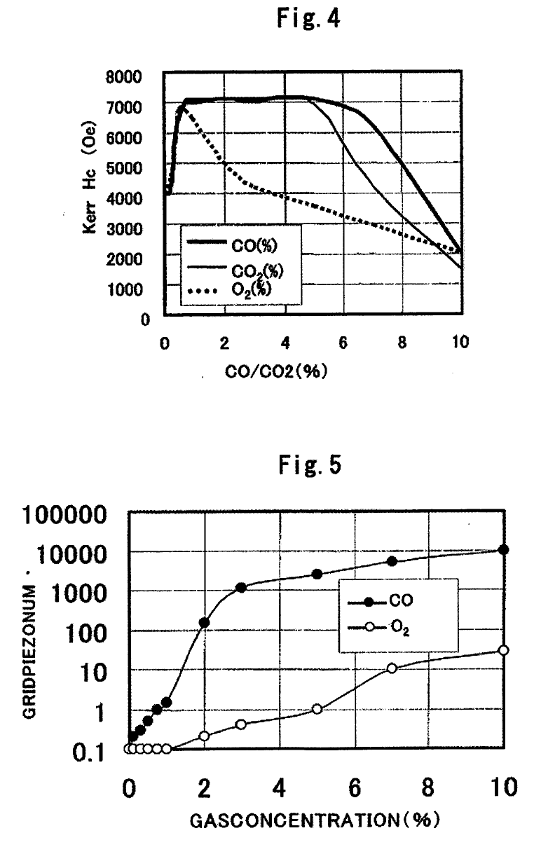

Finally, the protective layer 6 of DLC (5 nm thick) was formed by RF-CVD from a process gas (at 2.2 Pa) of ethylene containing 20% hydrogen and 2% nitrogen. The resulting magnetic recording medium was tested for magnetic properties in terms of Hc. The results are shown in FIG. 4.

In FIG. 4, the abscissa represents the content of CO or CO₂ in argon gas, and the ordinate represents the Kerr Hc (Oe) as one of the magnetic properties. It is noted from FIG. 4 that in the case of process gas incorporated with oxygen (O₂), the Kerr Hc reaches the peak when the content of oxygen is in a narrow range of 0.25 to 1% and it decreases with the increasing oxygen content. By contrast, the process gas incorporated with CO or CO₂ gives rise to samples with stable magnetic properties over the broad range of CO or CO₂ content from about 0.5% to about 6%. This means that CO or CO₂ allows a broad process latitude.

Thus, according to the process of the present invention, it is possible to form the magnetic layer by sputtering in a more stable manner than the conventional process which employs a process gas incorporated with oxygen.

Flying Performance of the Magnetic Head

The above-mentioned experimental results indicate that the magnetic recording medium has the maximum coercive force when the content of CO or CO₂ in the process gas is about 0.5 to 6%. However, it was found in experiments on the effect of oxygen in the process gas that the resulting magnetic recording medium adversely affects the head flying performance as the oxygen content increases and the magnet head is more likely to hit anomalous projections on the surface of the magnetic recording medium. With this taken into consideration, similar experiments were carried out to see the effect of CO₂ concentration on the flying performance of the magnetic head. The flying performance was evaluated by using a glide checking head with a flying height of 8 nm. This special head is provided with a piezoelectric element to detect contact with projections, so that the number of contacts is counted from signals from the detector. Evaluation in this manner makes it possible to optimize the amount of CO₂ gas to be added. Samples were prepared in the same way as in as samples measuring the coercive force Example 1.

Each sample was prepared as below by sputtering on a previously cleaned glass substrate, 65 mm in diameter and 0.635 mm in thickness, with a surface roughness (Ra) of 0.320 nm. First, the substrate was placed in the continuous multi-layer sputtering apparatus shown in FIG. 2. On the substrate was formed the adhesion layer 2 with 30 nm thick by sputtering with a target of Ni40Ta functioning as the DC magnetron cathode excited at 500 W. The chamber was supplied with argon (Ar) at 1.25 Pa.

Then, three magnetic domain fixing layers having respective thicknesses of 10, 20, and 5 nm were formed from NiFe20, Mnkr20, and CoFe30, respectively. The chamber was supplied with argon (Ar) at 1 Pa for each layer. The DC magnetron cathode was supplied with a power level of 500 W, 1 kW, and 300 W for respective layers.

Then, three layers as the soft magnetic layer 6 of APC-SUL structure were formed from Co10Ta5Zr (100 nm thick), Ru (1 nm thick), and Co10Ta5Zr (100 nm thick), respectively. The chamber was supplied with argon (Ar) at 0.6 Pa for each layer. The DC magnetron cathode was supplied with a power level of 2 kW for CoTaZr and 100 W for Ru.

The underlying layer of dual structure, composed of a Ta layer with 3 nm thick and a Ru layer with 15 nm thick, was formed by supplying the chamber with argon (Ar) at 1 Pa and 4 Pa, respectively.

The magnetic layer 10 was formed by using the DC magnetron cathode, with the process gas kept at 3.8 Pa and the DC power level kept at 500 W. Duration of layer forming was varied so that the resulting layer has a constant thickness of 16 nm. The target was composed of CoCrPt (15-18) plus 8 mol % of SiO₂. The process gas was Ar+CO₂ or Ar+O₂ for comparison. The ratio of CO₂ or O₂ to argon (Ar) was varied.

Finally, the protective layer 6 of DLC (3 nm thick) was formed by RF-CVD from a process gas (at 2.2 Pa) of ethylene containing 20% hydrogen and 2% nitrogen.

After the layer forming process was completed, the magnetic recording medium was discharged from the vacuum apparatus. It was finally finished with a fluorine-based lubricant by dip coating, so that a lubricating layer with 14 Å thick was formed. The finished surface was rubbed with a vanish head for removal of anomalous projections and dust. This step is intended for the magnetic head to maintain a prescribed flying height.

The flying performance was evaluated by using the glide tester. The results are shown in FIG. 5, in which GRIDPIEZONUM (the hit count on one side of the recording medium) is plotted against CONCENTRATION % (the concentration of CO or O₂ gas added).

It is noted from FIG. 5 that the flying performance becomes greatly poor when the concentration of oxygen exceeds 1%. By contrast, it is note that the flying performance remains good until the concentration of CO₂ reaches about 6%. This good flying performance is parallel to the good magnetic property shown in FIG. 4. This result suggests that incorporation with CO₂ gas greatly contributes to magnetic property as well as process reproducibility and quality improvement.

Stability of Production

In order to confirm the stability and reproducibility of the process according to the present invention, continuous operation equivalent to production of 30,000 pieces of recording media was carried out under the same condition as in Example 1, with the concentration of CO or CO₂ fixed at 3%. This concentration was chosen in view of the fact that the maximum coercive force was obtained in Example 1 when the concentration of CO or CO₂ was about 0.5 to 6%. The stability and reproducibility of the process were rated in terms of magnetic properties.

Samples were prepared in the following manner. Each sample was prepared as below by sputtering on a previously cleaned glass substrate, 65 mm in diameter and 0.635 mm in thickness, with a surface roughness (Ra) of 0.320 nm. First, the substrate was placed in the continuous multi-layer sputtering apparatus shown in FIG. 2. On the substrate was formed the adhesion layer 2 with 30 nm thick by sputtering with a target of Ni40Ta functioning as the DC magnetron cathode excited at 500 W. The chamber was supplied with argon (Ar) at 1.25 Pa.

Then, three magnetic domain fixing layers having respective thicknesses of 10, 20, and 5 nm were formed from NiFe20, MnIr20, and CoFe30, respectively. The chamber was supplied with argon (Ar) at 1 Pa for each layer. The DC magnetron cathode was supplied with a power level of 500 W, 1 kW, and 300 W for respective layers.

Then, three layers as the soft magnetic layer 6 of APC-SUL structure were formed from Co10Ta5Zr (100 nm thick), Ru (1 nm thick), and Co10Ta5Zr (100 nm thick), respectively. The chamber was supplied with argon (Ar) at 0.6 Pa for each layer. The DC magnetron cathode was supplied with a power level of 2 kW for CoTaZr and 100 W for Ru.

The underlying layer of dual structure, composed of a Ta layer with 3 nm thick and a Ru layer with 15 nm thick, was formed by supplying the chamber with argon (Ar) at 1 Pa and 4 Pa, respectively.

The magnetic layer 10 was formed by using the DC magnetron cathode, with the process gas kept at 3.8 Pa and the DC power level kept at 500 W. Duration of layer forming was varied so that the resulting layer may have a constant thickness of 16 nm. The target was composed of CoCrPt (18-17) plus 10 mol % of SiO₂. The process gas was Ar+3% CO or Ar+3% CO₂.

Finally, the protective layer 11 of DLC (5 nm thick) was formed by RF-CVD from a process gas (at 2.2 Pa) of ethylene containing 20% hydrogen and 2% nitrogen.

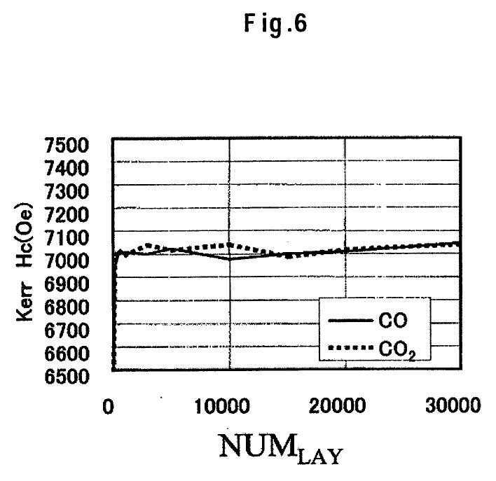

The thus obtained samples were tested for magnetic property in terms of Kerr Hc (Oe). The results are shown in FIG. 6, in which Kerr Hc is plotted against NUMLAY, which is the number of samples produced. For the purpose of comparison, the same procedure as mentioned above was repeated except that the carbon oxide gas was replaced by oxygen (O₂). The results are shown in FIG. 3.

It is noted from FIG. 6 that all the 30,000 samples kept about 7 kOe of coercive force (Hc). This indicates good stability and reproducibility in continuous operation. By contrast, it is noted that sputtering with argon plus oxygen in the presence of SiO₂ was poor in stability and reproducibility. The reason for this is that the added oxygen produces an oxygen-excess state and a non-equilibrium state, which leads to fluctuation in coercive force (Hc).

The process according to the present invention is stable and reproducible in production of magnetic recording media because it involves reactive sputtering in an equilibrium state that results from incorporation of CO or CO₂ into a process gas. The CO—═or CO₂-containing process gas for sputtering forms a magnetic layer having a high coercive force, and it can be used for any kind of sputtering, including AC sputtering, DC sputtering, RF sputtering, and DC-pulse sputtering, without restriction in the type of facility. The process allows a broad latitude and realizes a high productivity. The incorporation with CO or CO₂ stabilizes the magnetic layer forming step. In addition, CO or CO₂ can be evacuated more easily and rapidly than O₂ by a vacuum pump (usually a turbo-molecular pump). Therefore, this leads to a decrease in their adsorption to or accumulation on the inner surface of the vacuum chamber. The result is good vacuum quality and reproducible layer forming.

The present invention is not limited in its scope to the examples mentioned above; however, it may be applied to any process involving oxidation for thin film formation. It will be useful for reactive thin film formation in a stable equilibrium state. The present invention will realize a magnetic storage device excellent in magnetic properties if the magnetic recording medium is used in combination with an adequate magnetic head for perpendicular magnetic recording.

It is to be understood that the above description is intended to be illustrative and not restrictive. Many embodiments will be apparent to those of skill in the art upon reviewing the above description. The scope of the invention should, therefore, be determined not with reference to the above description, but instead should be determined with reference to the appended claims alone with their full scope of equivalents.

What is claimed is:

1. A method for producing a magnetic recording medium, comprising:
forming at least a soft magnetic layer and a magnetic layer above a substrate;
wherein forming said magnetic layer includes sputtering with argon gas and carbon oxide gas.

2. The method for producing a magnetic recording medium as defined in claim 1, wherein a ratio of said carbon oxide gas to said argon gas is about 0.5 to 6%.

3. The method for producing a magnetic recording medium as defined in claim 1, wherein said magnetic layer comprises cobalt, chromium, platinum, and carbon, and has a granular structure.

4. The method for producing a magnetic recording medium as defined in claim 3, wherein the soft magnetic layer has an antiparallel coupling structure.

5. The method for producing a magnetic recording medium as defined in claim 3, further comprising:
forming an adhesion layer between said soft magnetic layer and said substrate;
forming an underlying layer between said soft magnetic layer and said magnetic layer;
forming a protective layer above said magnetic layer; and
forming a lubricating layer above said protective layer.

6. The method for producing a magnetic recording medium as defined in claim 1, wherein said carbon oxide gas is carbon dioxide gas.

7. The method for producing a magnetic recording medium as defined in claim 1, wherein said carbon oxide gas is carbon monoxide gas.

8. The method for producing a magnetic recording medium as defined in claim 1, wherein said carbon oxide gas reduces excess oxygen in forming said magnetic layer.

9. A method for producing a magnetic recording medium, comprising:
forming an adhesion layer above a substrate;
forming a soft magnetic layer after forming said adhesion layer;
forming a magnetic layer by sputtering after forming said soft magnetic layer;
forming a protective layer after forming said magnetic layer; and
forming a lubricating layer after forming said protective layer;
wherein forming said magnetic layer involves incorporating carbon oxide gas.

10. The method for producing a magnetic recording medium as defined in claim 9, wherein said magnetic layer has a granular structure and includes cobalt, chromium, and platinum and also includes a silicon oxide in a grain boundary.

11. The method for producing a magnetic recording medium as defined in claim 9, further comprising forming a layer including ruthenium which is placed between said magnetic layer and said soft magnetic layer.

12. The method for producing a magnetic recording medium as defined in claim 9, wherein said protective layer includes diamond-like carbon, said soft magnetic layer has a first layer and a second layer and a non-magnetic layer interposed between said first layer and said second layer, and said first layer and said second layer include cobalt, tantalum, and zirconium.

13. The method for producing a magnetic recording medium as defined in claim 12, wherein said non-magnetic layer further includes ruthenium.

14. The method for producing a magnetic recording medium as defined in claim 13, wherein said carbon oxide is carbon monoxide.

15. The method for producing a magnetic recording medium as defined in claim 13, wherein said carbon oxide is carbon dioxide.

16. The method for producing a magnetic recording medium as defined in claim 9, wherein forming said magnetic layer permits argon gas to be introduced and a ratio of said carbon oxide to said argon gas is about 0.5 to 6%.

17. The method for producing a magnetic recording medium as defined in claim 9, wherein said magnetic layer has a thickness of no less than about 5 nm and no more than about 20 nm.
